(19) United States
(12) Patent Application Publication
(10) Pub. No.: US 2024/0153767 A1
(43) Pub. Date: May 9, 2024

(54) SEMICONDUCTING OXIDE CHANNEL FOR 3D NAND AND METHOD OF MAKING

(71) Applicant: ASM IP Holding B.V., Almere (NL)

(72) Inventors: Bart Vermeulen, Dresden (DE); Varun Sharma, Helsinki (FI); Andrea Illiberi, Leuven (BE); Michael Givens, Oud-Heverlee (BE); Charles Dezelah, Helsinki (FI); Eric Shero, Phoenix, AZ (US)

(21) Appl. No.: 18/386,128

(22) Filed: Nov. 1, 2023

Related U.S. Application Data
(60) Provisional application No. 63/422,451, filed on Nov. 4, 2022.

(51) Int. Cl. H01L 21/02; H01L 29/24; H01L 29/267; H01L 29/792; H10B 43/27

(52) U.S. Cl. CPC H01L 21/02565; H01L 21/02579; H01L 21/0262; H01L 29/24; H01L 29/242; H01L 29/267; H01L 29/792; H10B 43/27

(57) ABSTRACT

Disclosed are methods and systems for depositing layers including a p-type semiconducting oxide onto a surface of a substrate. The deposition process includes a cyclical deposition process. Exemplary structures in which the layers may be incorporated include 3D NAND cells, memory devices, metal-insulator-metal structured, and DRAM capacitors.

### CROSS-REFERENCE TO RELATED APPLICATIONS

This application claims priority to and the benefit of U.S. Provisional Application No. 63/422,451, filed Nov. 4, 2022, the entirety of which is incorporated by reference herein.

### FIELD OF INVENTION

The present disclosure relates to the field of semiconductor processing methods and systems. In particular, methods and systems for forming semiconducting oxide layers are disclosed.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges for future technology nodes.

For example, one challenge has been finding a suitable material for use as a semiconducting channel in CMOS devices. Various n-type semiconducting oxide materials might be used, such as, for example, IGZO or ITO layer. However, these n-type semiconducting oxides only support conduction via majority electron transport, and minority carriers do not exist in the materials in appreciable quantities. Therefore, In NAND, n-type semiconducting oxides cannot support the standard ERASE function and cannot be utilized in conventional NAND unless ERASE scheme is modified to ERASE via application of large reverse bias across the layers to drive electrons out of the charge trapping layer deep traps back into the channel. This, however, greatly increases the ERASE voltage required.

In addition, there remains a need for new materials in other semiconductor devices such as MIM (metal-insulator-metal) structures, DRAM capacitors, and 3D NAND cells.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods depositing a p-type semiconducting oxide layer, to structures and devices formed using such methods, and to apparatus for performing the methods and/or forming the structures and/devices. The layers may be used in a variety of applications, including work function adjustment layers, and threshold voltage adjustment layers. For example, they may be used in a channel in n- or p-channel metal oxide semiconductor field effect transistors (MOSFETS).

Described herein is a method for depositing p-type semiconducting oxide layer on a substrate by a cyclic deposition process. The method comprises providing a substrate in a reactor chamber and executing a plurality of cycles which comprises providing a first and second metal precursor into the reactor chamber in vapor phase. The first metal precursor is provided during a first metal precursor pulse and the second metal precursor is provided during a second metal precursor pulse. Finally, an chalcogenide reactant is provided into the reactor chamber in vapor phase during an chalcogenide reactant pulse. In addition, the first metal precursor may be provided into the reactor chamber before the second metal precursor, the first and second metal precursor pulses may be at least partially overlapping and the first and second metal precursor are mutually different.

Further, described herein is a memory element. The memory element can comprise, a gate electrode, a blocking dielectric adjacent to the gate electrode, a tunnel dielectric, a charge trapping layer being positioned between the blocking dielectric and the tunnel dielectric, an n-type layer, and a p-type layer. In some embodiments, the memory element can comprise, in the following order, a gate electrode, a blocking dielectric, a charge trapping layer, a tunnel dielectric, an n-type layer, and a p-type layer. The n-type layer comprises an n-type semiconducting oxide and the p-type layer comprises a p-type semiconducting oxide.

Further, described herein is a gate stack 3D NAND memory. The 3D NAND memory comprises a vertical channel and a plurality of floating gate stacks. The floating gate stacks each comprise a tunnel dielectric adjacent to the vertical channel, a charge trapping layer adjacent to the tunnel dielectric, a blocking dielectric adjacent to the charge trapping layer, and a gate electrode adjacent to the blocking dielectric. The vertical channel comprises a p-type layer and an n-type layer, wherein the n-type layer comprises an n-type semiconducting oxide and the p-type layer comprises a p-type semiconducting oxide.

Further, described herein is a system. The system comprises one or more reaction chambers constructed and arranged to hold a substrate, a first metal precursor vessel constructed and arranged to contain and evaporate a first metal precursor, a second metal precursor vessel constructed and arranged to contain and evaporate a second metal precursor and a controller. The controller is configured to control gas flow of the first precursor and the second precursor into the one or more reaction chambers to form a layer on a substrate comprised in the reaction chamber by means of a method according to the current description.

These and other embodiments will become readily apparent to those skilled in the art from the following detailed description of certain embodiments having reference to the attached figures. The invention is not limited to any particular embodiments disclosed.

In the current disclosure, a p-type semiconducting oxide (pSCO) featuring degenerate concentration of holes can be deposited adjacent to the n-type semiconducting oxide (nSCO) channel in the center of the channel holes by an ALD process. This pSCO acts as hole source into and through the nSCO and tunnel oxide to support ERASE function. In this structure, the channel hole stack is deposited by an ALD process. The structure from the outside diameter of the hole to the middle is: blocking oxide-charge trapping layer-tunnel oxide-nSCO-pSCO. In some embodiments, the pSCO deposition can occur at lower thermal budget than the nSCO deposition.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates an embodiment of a method as disclosed herein;

FIG. 2 illustrates a VNAND cell in accordance with some embodiment of the current disclosure;

FIG. 3 shows a structure in accordance with some embodiments of the current disclosure;

FIG. 4 shows an embodiment of a substrate processing system in accordance with some embodiments of the current disclosure.

FIG. 5 illustrates a system in accordance with exemplary embodiments of the disclosure.

FIG. 6 shows a system in accordance with some embodiments of the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The illustrations presented herein are not meant to be actual views of any particular material, structure, or device, but are merely idealized representations that are used to describe embodiments of the disclosure.

The particular implementations shown and described are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may partially or wholly consist of a plurality of dispersed atoms on a surface of a substrate and/or embedded in a substrate/and/or embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices.

As used herein, a “structure” can be or include a substrate as described herein. Structures can include one or more layers overlying the substrate, such as one or more layers formed according to a method as described herein. Device portions can be or include structures.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es).

Generally, for ALD processes, during each cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using an inert gas such as a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein. The terms “precursor” and “reactant” can be used interchangeably.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments.

In this disclosure, any defined meanings do not necessarily exclude ordinary and customary meanings, in some embodiments.

According to one aspect of the present disclosure, described herein is a method of depositing p-type semiconducting oxide layer on a substrate by a cyclic deposition process. The method comprises the steps of first providing a substrate in a reactor chamber and secondly executing a plurality of deposition cycles. A deposition cycle comprises providing a first and second metal precursor into the reactor chamber in vapor phase, the first metal precursor being provided during a first metal precursor pulse and the second metal precursor being provided during a second metal precursor pulse, and providing a chalcogenide reactant to the reactor chamber into vapor phase during a chalcogenide reactant pulse. Thus, the layer is formed on the substrate. In some embodiments, the first metal precursor is provided to the reactor chamber before the second metal precursor. In some embodiments, the first and second metal precursor pulses are at least partially overlapping. In some embodiments, the first and second metal precursor are mutually different. In some embodiments, the first metal precursor is provided to the reactor chamber before the second metal precursor, the first and second metal precursor pulses are at least partially overlapping, the first and second metal precursor are mutually different.

According to a further aspect of the current disclosure, described herein is a further method of depositing a semiconducting oxide layer on a substrate by a cyclic deposition process. The method comprises the steps of first providing a substrate in a reactor chamber and secondly executing a plurality of deposition cycles. A deposition cycle comprises providing a first metal precursor into the reactor chamber in vapor phase, the first metal precursor being provided during a first metal precursor pulse. A deposition cycle further comprises a chalcogenide pulse in which a chalcogenide reactant is provided to the reactor chamber in the vapor phase. Thus the layer is formed on the substrate. In some embodiments, such a method can be employed for forming an n-type semiconducting layer. Alternatively, such a method can be employed for forming a p-type semiconducting layer.

It shall be understood that depositing a layer as described herein comprises a cyclical deposition process. The cyclical deposition process can include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, i.e. of non-self-limiting gas phase reactions, but still taking advantage of the sequential introduction of reactants. Such a process may be referred to as cyclical CVD. In some embodiments, a cyclical CVD process may comprise the introduction of two or more precursors or reactants into the reaction chamber, wherein there may be a time period of overlap between the two or more reactants in the reaction chamber resulting in both an ALD component of the deposition and a CVD component of the deposition. This is referred to as a hybrid process. In accordance with further examples, a cyclical deposition process may comprise a continuous flow of one reactant or precursor and periodic pulsing of a second reactant or precursor into the reaction chamber.

In one embodiment the p-type semiconducting oxide layer formed on the substrate is selected from the group consisting of. Cu₂O, NiO and alloys of Cu₂O and NiO. In another embodiment Cu₂O and NiO can be alloyed with the alloying elements selected from the list consisting of Ga, Al, Mg, Mn, Bi, Sr, B, N, Sc, Li, V, S, Ni, Cr, Sn, Sb, La, Y, Mo, P and N. The concentration of the alloying elements may be from at least 0.05 atomic percent to at most 0.2, atomic percent, from at least 0.2 atomic percent to at most 1 atomic percent, from at least 1 atomic percent to at most 5 atomic percent, or from at least 5 atomic percent to at most 10 atomic percent.

In one embodiment, the metal precursors are pulsed simultaneously. In one embodiment the metal precursors do not react with one another. In this process the purge time is halved compared to a standard process that has a purge step after each metal precursor pulse. In one embodiment the co-dosing process is as follows:
First metal precursor and Second metal precursor+purge+chalcogenide reactant+purge

According to one embodiment, the first metal precursor pulse and the second metal precursor pulse are separated by a purge.

A layer having a desired thickness can be formed on the substrate by executing a suitable number of deposition cycles. The total number of deposition cycles comprised in a method as described herein depends, inter alia, on the total layer thickness that is desired. In some embodiments, the method comprises from at least 2 deposition cycles to at most 5 deposition cycles, or from at least 5 deposition cycles to at most 10 deposition cycles, or from at least 10 deposition cycles to at most 20 deposition cycles, or from at least 20 deposition cycles to at most 50 deposition cycles, or from at least 50 deposition cycles to at most 100 deposition cycles, or from at least 100 deposition cycles to at most 200 deposition cycles, or from at least 200 deposition cycles to at most 500 deposition cycles, or from at least 500 deposition cycles to at most 1000 deposition cycles, or from at least 1000 deposition cycles to at most 2000 deposition cycles, or from at least 2000 deposition cycles to at most 5000 deposition cycles, or from at least 5000 deposition cycles to at most 10000 deposition cycles.

According to one embodiment, the first and second metal precursor each independently comprise a ligand chosen from amongst the following groups: β-diketonate, alkoxide, diazadiene, amidinate, carboxylate, and cyclopentadienyl. According to one embodiment, the first and second metal precursors comprise a metal atom that can be either Ni or Cu. In one embodiment, the first metal precursor is different than the second metal precursor. According to some embodiments, the first or second metal precursor can comprise a β-diketonate ligand, including but not limited to examples such as acetylacetonate (acac), 2,2,6,6-tetramethyl-3,5-heptanedionate (thd), hexafluoroacetylacetonate (hfac). Examples of precursors containing a β-diketonate ligand include Ni(thd)₂, Ni(acac)₂, Ni(hfac)₂, Cu(acac)₂, Cu(thd)₂, Cu(hfac)₂, Cu(hfac)(vinyltrimethylsilane), Cu(hfac)(3,3-dimethyl-1-butene) and Cu(acac)(tri-n-butylphosphine).

According to some embodiments, the first or second metal precursor can comprise an alkoxide ligand. In some embodiments, the alkoxide comprises a dialkylaminoalkoxide. In some embodiments, the alkoxide comprises a 2-dialkylaminoethoxide, 2-dialkylaminopropoxide, or 3-dialkylaminopropoxide. In some embodiments, the alkoxide is methoxide, ethoxide, isopropoxide, 1-propoxide, tert-butyoxide, 1-dimethylamino-2-propoxide (dmap), 3-(Dimethylamino)-2-methyl-2-butoxide (dmamp), or 2-(Dimethylamino)-3-methyl-3-pentoxide (dmamb). Examples of precursors include Ni(dmap)₂, Ni(dmamb)₂, Ni(dmamp)₂, Cu(dmap)₂, Cu(dmamb)₂, and Cu(dmamp)₂.

According to some embodiments, the first or second precursor comprises a diazadiene ligand. In some embodiments, the ligand is 1,4-di-tert-butyl-1,3-diazadiene (tBu₂DAD). In some embodiments, the ligand is 1,4-diisopropyl-1,3-diazadiene (iPr₂DAD). In some embodiments, the ligand is 1,4-di-tert-pentyl-1,3-diazadiene (tPn₂DAD). In some embodiments, the ligand is 1,4-di-sec-butyl-1,3-diazadiene (sBu₂DAD). Examples of precursors include Ni(tBU₂DAD)₂, Ni(iPr₂DAD)₂, and Ni(tPn₂DAD)_{2.}

According to some embodiments, the first or second precursor comprises an amidinate ligand. In some embodiments, the ligand is N,N′-diisopropylacetamidinate (iPr₂AMD). In some embodiments, the ligand is N,N′-di-tert-butylacetamidinate (tBu₂AMD). In some embodiments, the ligand is N,N′-diisopropylformamidinate (iPr₂FMD) In some embodiments, the ligand is N,N′-di-tert-butylformamidinate (tBu₂FMD). In some embodiments, the ligand is N,N′-di-see-butylacetamidinate (sBu₂AMD). In some embodiments, the ligand is N,N′di-sec-butylformamidinate (sBuP₂FMD). Examples of precursors include Ni(tBu₂AMD)₂, Ni(iPr₂AMD)₂, Ni(iPr₂FMD)₂, Cu₂(iPr₂AMD)₂ and Cu₂(sBu₂AMD)₂.

According to some embodiments, the first or second precursor comprises a carboxylate ligand. In some embodiments, the ligand is pivolate (Pv). In some embodiments, the ligand is acetate (OAc). Examples of precursors include Cu(Pv)₂ and Cu(OAc)₂.

According to some embodiments, the first or second precursor comprises a cyclopentadienyl ligand. In some embodiments, the ligand is cyclopentadientyl (Cp). In some embodiments, the ligand is methylcyclopentadientyl (MeCp). In some embodiments, the ligand is ethylcyclopentadientyl (EtCp). In some embodiments, the ligand is n-propylcyclopentadientyl (nPrCp). In some embodiments, the ligand is isopropylcyclopentadientyl (iPrCp). In some embodiments, the ligand is n-butylcyclopentadientyl (nBuCp). In some embodiments, the ligand is tert-butylcyclopentadientyl (tBuCp). In some embodiments, the ligand is set-butylcyclopentadientyl (sBuCp). In some embodiments, the ligand is trimethylsilylcyclopentadientyl (TMSCp). In some embodiments, the ligand is pentamethyleyclopentadientyl (Cp*). Examples include Cu(Cp)₂, Ni(Cp)₂, Ni(MeCp)₂, Ni(EtCp)₂, and CuCp(PEt₃).

According to one embodiment, the chalcogenide reactant is used to at least partially modify, such as oxidize, the deposited layer. A suitable chalcogenide reactant is chosen from the group consisting of atmospheric air, ozone, water, O₂, hydrogen peroxide, O-containing plasma, O-radicals, N₂O, NO, N₂O₅, H₂S, H₂S plasma, H₂Se, Et₂Se, Se₂(Si(iPr)₂)₂, [(CH₃)₃Si]₂Se, [(CH₃)₃Si]₂Te, Te[OiPr]₄ and mixtures thereof.

According to one embodiment, the method further comprises providing a dopant precursor into the reaction chamber in a dopant precursor pulse.

In some embodiments, the plurality of deposition cycles can comprise a plurality of master cycles. A master cycle can comprise a dopant precursor pulse and one or more sub-cycles. A sub-cycle comprises a chalcogenide reactant pulse followed by a metal precursor pulse. Thus, in some embodiments, the plurality of deposition cycles can be represented by formula i)

[(Chalcogenide reactant+Metal precursor)×sub-cycle+Dopant precursor]×master cycle i)

In which “chalcogenide reactant” denoted a chalcogenide reactant pulse, “metal precursor” denoted a metal precursor pulse, “×sub-cycle” denotes the number of sub-cycles per master cycle, “dopant precursor” denoted a dopant precursor pulse, “×master cycle” denotes the number of master cycles, and “+” denotes that one pulse occurs after the other. In such embodiments, a dopant precursor pulse can directly follow a metal precursor pulse, such that the substrate surface is saturated with metal precursor, and the amount of dopant incorporated in the resulting film is limited. This is advantageous to obtain low dopant levels in the resulting film.

Additionally or alternatively, and in some embodiments, the metal precursor pulse precede the chalcogenide reactant pulse, giving rise to a cyclical deposition process that can be described by formula ii)

[(Metal precursor+Chalcogenide reactant)×sub-cycle+Dopant precursor]×master cycle ii)

In some embodiments, a metal precursor pulse can be executed before executing the master cycles, as indicated by formula iii)

[Metal precursor+[(Chalcogenide reactant+Metal precursor)×sub-cycle+Dopant precursor]×master cycle iii)

In some embodiments, the method comprises from at least 2 master cycles to at most 5 master cycles, or from at least 5 master cycles to at most 10 master cycles, or from at least 10 master cycles to at most 20 master cycles, or from at least 20 master cycles to at most 50 master cycles, or from at least 50 master cycles to at most 100 master cycles, or from at least 100 master cycles to at most 200 master cycles, or from at least 200 master cycles to at most 500 master cycles, or from at least 500 master cycles to at most 1000 master cycles, or from at least 1000 master cycles to at most 2000 master cycles, or from at least 2000 master cycles to at most 5000 master cycles, or from at least 5000 master cycles to at most 10000 master cycles. The method comprises from at least 2 sub-cycles to at most 5 sub-cycles, or from at least 5 sub-cycles to at most 10 sub-cycles, or from at least 10 sub-cycles to at most 20 sub-cycles, or from at least 20 sub-cycles to at most 50 sub-cycles, or from at least 50 sub-cycles to at most 100 sub-cycles, or from at least 100 sub-cycles to at most 200 sub-cycles, or from at least 200 sub-cycles to at most 500 sub-cycles, or from at least 500 sub-cycles to at most 1000 sub-cycles, or from at least 1000 sub-cycles to at most 2000 sub-cycles.

According to one embodiment the dopant precursor comprises any element that reacts with water. In one embodiment the dopant precursor comprises one or more elements selected from the group consisting of Mn, Bi, Sr, B, N, Li, V, S, Sc, P, N, K, Na, Ni, Ga, Mg, and Al. In some embodiments, when the semiconducting oxide layer comprises Cu₂O the dopant precursor comprises one or more elements selected from the list of: Ni, Mn, Bi, Mg, Sr, B, N, Mg and Al. In some embodiments, when the semiconducting oxide layer comprises NiO the dopant precursor comprises one or more elements selected from the list of: Cu, Al, Ga, Sc, Li, V, S, P, N K and Na. In one embodiment the dopant precursor comprises an alkali metal. In one embodiment the dopant precursor comprises an alkaline earth metal. In one embodiment the dopant precursor comprises a transition metal. In one embodiment the dopant precursor comprises a post transition metal. In one embodiment the dopant precursor comprises a group 14 element. In one embodiment the dopant precursor is selected from the group consisting of methylaluminum diisopropoxide (Al(Me)[iOPr]₂), bis(cyclopenthadienyl)magnesium (Mg[Cp]₂) and dimethylaluminum isopropoxide (AlMe₂[iOPr]).

According to one embodiment, the first and second precursors are provided into the reactor chamber at a temperature range of about 80° C. to about 400° C. For example, first and second metal precursor may be deposited at a temperature from about 100° C. to about 400° C., or at a temperature from about 150° C. to about 350° C. In some embodiments of the current disclosure, first and second metal precursor may be deposited at a temperature from about 260° C. to about 330° C., or at a temperature from about 270° C. to about 330° C. In some embodiments, first and second metal precursor may be deposited at a temperature from about 150° C. to about 200° C., or at a temperature from about 300° C. to about 400° C., or at a temperature from about 280° C. to about 320° C. For example, first and second metal precursor may be deposited at a temperature of about 210° C. or about 225° C. or about 285° C., or about 290° C., or about 310° C., or about 315° C. or about 325° C., or about 375° C., or about 380° C., or about 385° C., or about 390° C.

A pressure in a reaction chamber may be selected independently for different process steps. In some embodiments, a first pressure may be used during transition metal precursor pulse, and a second pressure may be used during haloalkane precursor pulse. A third or a further pressure may be used during purging or other process steps. In some embodiments, a pressure within the reaction chamber during the deposition process is less than 760 Torr, or a pressure within the reaction chamber during the deposition process is between 0.2 Torr and 760 Torr, or between 1 Torr and 100 Torr, or between 1 Torr and 10 Torr. In some embodiments, a pressure within the reaction chamber during the deposition process is less than about 0.001 Torr, less than 0.01 Torr, less than 0.1 Torr, less than 1 Torr, less than 10 Torr, less than 50 Torr, less than 100 Torr or less than 300 Torr. In some embodiments, a pressure within the reaction chamber during at least a part of the method according to the current disclosure is less than about 0.001 Torr, less than 0.01 Torr, less than 0.1 Torr, less than 1 Torr, less than 10 Torr or less than 50 Torr, less than 100 Torr or less than 300 Torr. For example, in some embodiments, a first pressure may be about 0.1 Torr, about 0.5 Torr, about 1 Torr, about 5 Torr, about 10 Torr, about 20 Torr or about 50 Torr. In some embodiments, a second pressure is about 0.1 Torr, about 0.5 Torr, about 1 Torr, about 5 Torr, about 10 Torr, about 20 Torr or about 50 Torr.

In some embodiments, the layer formed on the substrate has a thickness from at least 0.2 nm to at most 30 nm, or from at least 0.3 nm to at most 25 nm, or from at least 0.4 nm to at most 20 nm, or from at least 0.5 nm to at most 15 nm, or from at least 0.7 nm to at most 10 nm or of at least 0.9 nm to at most 5 nm.

In some embodiments, the first metal precursor pulse lasts from at least 0.01 s to at most 240 s, or from at least 0.02 s to at most 120 s, or from at least 0.05 s to at most 60 s, or form at least 0.1 s to at most 30 s, or form at least 0.2 s to at most 15 s, or from at least 0.25 s to at most 6.0 s, or from at least 0.5 s to at most 4.0 s, or from at least 1.0 s to at most 3.0 s.

In some embodiments, the second metal precursor pulse lasts from at least 0.01 s to at most 240 s, or from at least 0.02 s to at most 120 s, or from at least 0.05 s to at most 60 s, or form at least 0.1 s to at most 30 s, or form at least 0.2 s to at most 15 s, or from at least 0.25 s to at most 6.0 s, or from at least 0.5 s to at most 4.0 s, or from at least 1.0 s to at most 3.0 s.

In some embodiments, the dopant precursor pulse lasts from at least 0.5 s to at most 20.0 s, or from at least 1.0 s to at most 12.0 s, or from at least 4.0 s to at most 8.0 s.

According to one aspect of the disclosure, there is provided a memory element. The memory element comprises a gate electrode, a blocking dielectric adjacent to the gate electrode, a tunnel dielectric, a charge trapping layer positioned between the blocking dielectric and the tunnel dielectric, a p-type layer, and an n-type layer. The n-type layer comprises an n-type semiconducting oxide, and the p-type layer comprises a p-type semiconducting oxide.

According to one embodiment, the p-type semiconducting oxide comprises nickel oxide (NiO).

According to one embodiment, the p-type semiconducting oxide comprises cuprous oxide (Cu₂O).

According to one embodiment, the n-type semiconducting oxide comprises oxygen and one or more of aluminum, gallium, indium, magnesium, scandium, tungsten, tin, and zinc.

According to one embodiment, the n-type layer is positioned between the tunnel dielectric and the p-type layer.

According to one embodiment, there is provided a gate stacked 3D NAND memory. The gate stacked 3D NAND comprises a vertical channel and a plurality of floating gate stacks, the floating gate stacks each comprising a tunnel dielectric adjacent to the vertical channel, a charge trapping layer adjacent to the tunnel dielectric, a blocking dielectric adjacent to the charge trapping layer, and a gate electrode adjacent to the blocking dielectric. The vertical channel comprises a p-type layer and an n-type layer. The n-type layer comprises an n-type semiconducting oxide, and the p-type layer comprises a p-type semiconducting oxide.

According to one embodiment, the p-type layer is deposited by means of a method according to the above disclosure.

According to one embodiment, the n-type layer forms a cylindrical shell around the p-type layer.

According to one embodiment, the gate stacked 3D NAND memory further comprises a memory element according to the above disclosure.

According to one aspect of the current disclosure, there is provided a system. The system comprises one or more reaction chambers constructed and arranged to hold a substrate; a first metal precursor vessel constructed and arranged to contain and evaporate a first metal precursor; a second metal precursor vessel constructed and arranged to contain and evaporate a second metal precursor; and a controller. The controller is configured to control gas flow of the first precursor and second precursor into the reaction chamber to form a layer on a substrate comprised in the reaction chamber by means of a method as described herein.

According to one embodiment, the system further comprises a chalcogenide reactant input constructed and arranged to provide a chalcogenide reactant to the reaction chamber.

Further described herein is a system that comprises a first reaction chamber. The first reaction chamber is constructed and arranged to hold a substrate. The first reaction chamber is operationally connected to a first precursor module and a first chalcogenide reactant module. The first precursor module comprises one or more first metal sources comprising one or more first metal precursors. The first chalcogenide reactant module comprises one or more first chalcogenide sources comprising one or more first chalcogenide reactants. The system further comprises a controller that is constructed and arranged for causing the system to provide one or more of the first metal precursors and one or more of the first chalcogenide reactant sources to the reaction chamber. Suitable first metal precursors include metal precursors as described herein. Suitable first chalcogenide reactants include oxidizers as described herein. Suitable first chalcogenide reactants can comprise one or more chalcogenides other than oxygen, such as at least one of S, Se, and Te.

In some embodiments, the system further comprises a second reaction chamber. The second reaction chamber is constructed and arranged to hold a substrate. The second reaction chamber is operationally connected to a second precursor module and a second chalcogenide reactant module. The second precursor module comprises one or more second metal sources comprising one or more second metal precursors. The second chalcogenide reactant module comprises one or more second chalcogenide sources comprising one or more second chalcogenide reactants. The system further comprises a controller that is constructed and arranged for causing the system to provide one or more of the second metal precursors and one or more of the second chalcogenide reactant sources to the second reaction chamber. Suitable second metal precursors include metal precursors as described herein. Suitable second chalcogenide reactants include oxidizers as described herein. Suitable second chalcogenide reactants can comprise one or more chalcogenides other than oxygen, such as at least one of S, Se, and Te.

In some embodiments, the one or more first metal precursors are different from the one or more second metal precursors. In some embodiments, the one or more first metal precursor are identical to the one or more second metal precursors.

In some embodiments, the one or more first chalcogenide reactants are different from the one or more second chalcogenide reactants. In some embodiments, the one or more first chalcogenide reactants are identical to the one or more second chalcogenide reactants.

In some embodiment, the system further comprises a transfer module comprising a wafer handling robot. The controller can be suitably constructed and arranged for causing the wafer handling robot to transfer a wafer from the first reaction chamber to the second reaction chamber, via the transfer module, while keeping the substrate in vacuum.

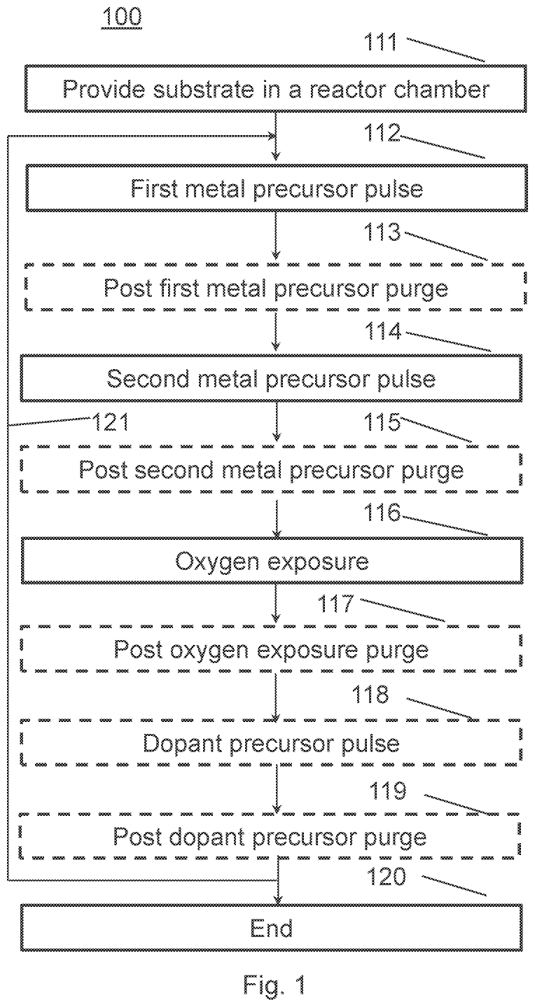

FIG. 1 shows a schematic representation of an embodiment of a method as described herein. The method (100) can be used to, for example, form a semiconducting oxide structure suitable for 3D NAND devices. However, unless otherwise noted, the presently described methods are not limited to such applications. The method according to FIG. 1 comprises step (111) of providing a substrate into a reaction chamber. The substrate is provided into the reaction chamber by positioning it on a substrate support which is positioned in a reaction chamber. Suitable substrate supports include pedestals, susceptors, and the like. An first metal precursor pulse (112) is then carried out. During the first metal precursor pulse, a first metal precursor is provided to the reaction chamber.

Optionally, the reaction chamber is then purged (113) by means of a post first metal precursor purge. Purging can be done by, for example, by means of a noble gas. Exemplary noble gasses include He, Ne, Ar, Xe and Kr. Alternatively, the purging can comprise transporting the substrate through a purge gas curtain. During a purge, surplus chemicals and reaction byproducts, if any, can be removed from the substrate surface or reaction chamber, such as by purging the reaction space or by moving the substrate, before the substrate is contacted with the next reactive chemical. Then, a second metal precursor pulse (114) is carried out by providing a second metal precursor into the reaction chamber. Optionally, the reaction chamber is then purged (115) by means of a post second metal precursor purge. Alternatively, the post second metal precursor purge can comprise transporting the substrate through a purge curtain gas.

Then, the substrate is exposed to an oxygen-containing gas, such as O₂, before the next step of the method is performed. Such an oxygen exposure step (116) can be used to further tune the effective work function of an electrode comprising a layer that is deposited according to an embodiment of a method as described herein. Optionally, the reaction chamber is then purged (117) by means of a post oxygen exposure purge. Alternatively, the post oxygen exposure purge can comprise transporting the substrate through a purge curtain gas.

Optionally, there is a dopant precursor pulse (118) step. In this step a dopant precursor is provided into the reaction chamber. After the dopant precursor pulse (118) there may be a post dopant precursor purge (119) step to purge the reaction chamber to remove any excess dopant precursor.

A deposition cycle comprising the first metal precursor pulse (112), the second metal precursor pulse (114) and the oxygen exposure (116) is repeated (121) one or more times. This method is continued until a layer having a pre-determined thickness is formed on the substrate. When a suitable thickness is obtained, the method can end (120), and subsequent layers can be deposited on top of this layer.

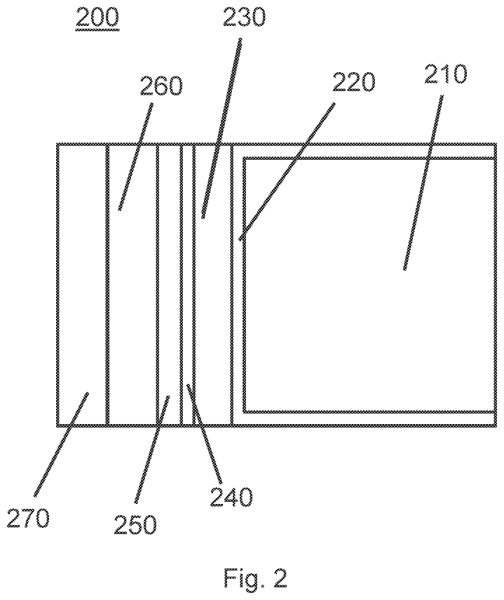

FIG. 2 illustrates a 3D NAND cell (200). The 3D NAND cell (200) comprises a metal layer (210). The metal layer (210) may be made from a metal such as copper, tungsten, etc. Alternatively, the metal layer (210) may comprise a layer that is deposited according to a method as described herein. As illustrated in FIG. 2, the metal layer (210) may be lined with an optional liner (220). The liner may improve adhesion and/or may prevent or at least minimize out diffusion of metal, e.g. copper or tungsten, from the metal layer (210).

The 3D NAND cell (200) further comprises a charge trapping layer (240). The charge trapping layer (240) is positioned between two dielectric layers (230,250): a blocking dielectric (230) and a tunnel dielectric (250). The charge trapping layer (240) may comprise a dielectric that has a smaller band gap than the adjacent blocking dielectric (230) and tunnel dielectric (250). The blocking dielectric (230) is adjacent to the liner (220). For example, the blocking dielectric (230) and the tunnel dielectric (250) can comprise silicon oxide, and the charge trapping layer (240) can comprise silicon nitride. Additionally or alternatively, the blocking dielectric (230) and the tunnel dielectric (250) can comprise one or more high-k dielectrics. For example, the one or more high-k dielectrics may be selected from the list comprising hafnium oxide (HfO₂), tantalum oxide (Ta₂O₅), vanadium oxide (VO₂), niobium oxide (Nb₂O₅), zirconium oxide (ZrO₂), titanium oxide (TiO₂), aluminum oxide (Al₂O₃) or lanthanum oxide (La₂O₃), and mixtures/laminates thereof. Other exemplary high-k dielectrics include silicates such as hafnium silicate (HfSiOₓ), lanthanum silicate (LaSiOₓ), titanium silicate (TiSiOₓ), and thulium silicate (TmSiOₓ), amongst others. In some embodiments, the tunneling dielectric can comprise a resonant tunneling structure. For example, a resonant tunneling structure can comprise a silicon nitride layer between two silicon oxide layers.

The 3D NAND cell (200) further comprises a first semiconducting oxide (260) and a second semiconducting oxide (270). The first semiconducting oxide (260) and the second semiconducting oxide (270) have a different conductivity type. For example, the first semiconducting oxide (260) can be an n-type semiconducting oxide and the second semiconducting oxide (270) can be a p-type semiconducting oxide.

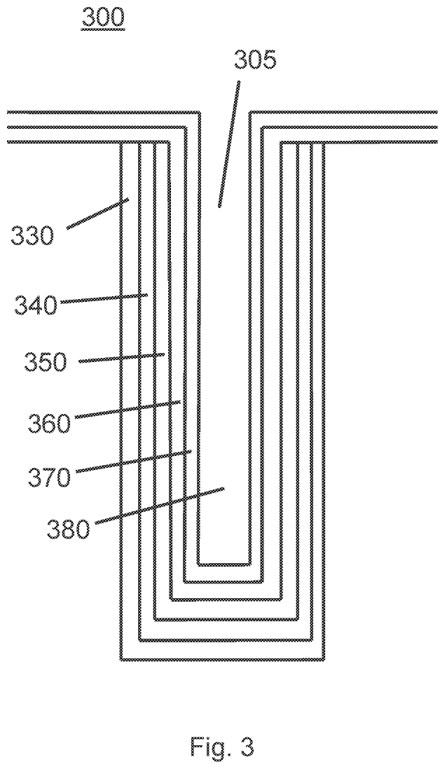

FIG. 3 shows a structure (300). The structure (300) can be further processed into a part of a 3D NAND memory circuit. The structure (300) comprises a gap (305). The gap (305) is lined, in the order given, with a blocking dielectric (330), a charge trapping dielectric (340), a tunnel dielectric (350), a first semiconducting oxide (360) and a second semiconducting oxide (370). The first semiconducting oxide (360) and the second semiconducting oxide (370) have a different conductivity type. The structure (300) of FIG. 3 can be manufactured in any suitable processing system.

For example, the structure (300) can be formed in a processing system comprising a first semiconducting oxide reaction chamber and a second semiconducting oxide reaction chamber, the first semiconducting oxide reaction chamber and the second semiconducting reaction chamber being different. The system further comprises a robotic arm and a controller. The controller is arranged for detecting a substrate in a substrate receiving module, such as a Front Opening Universal Pod (FOUP). The substrate comprises a gap. The gap is lined, in the order given, with the blocking dielectric (330), the charge trapping dielectric (340), and the tunnel dielectric (350). In one embodiment the blocking dielectric, the charge trapping dielectric and the tunnel dielectric are lined by means of a cyclical deposition technique such as atomic layer deposition (ALD). Each step is performed in their separate reaction chambers. It shall be understood that transport from the blocking dielectric reaction chamber to the the charge trapping dielectric reaction chamber and further to the tunnel dielectric reaction chamber suitably occurs without any intervening vacuum breaks.

The controller is further arranged for causing the robotic arm to provide the substrate to the first semiconducting oxide reaction chamber, and for causing the first semiconducting oxide reaction chamber to form the first semiconducting oxide layer (360) on the substrate, for example by means of a cyclical deposition technique such as atomic layer deposition (ALD). The controller is further arranged for causing the robotic arm to provide the substrate to the second semiconducting oxide reaction chamber after the first semiconducting oxide has been deposited. It shall be understood that transport from the first to the second semiconducting oxide reaction chamber suitably occurs without any intervening vacuum break. The controller is further arranged for causing the second semiconducting oxide reaction chamber to form the second semiconducting oxide layer (370) on the substrate, for example by means of a cyclical deposition technique such as atomic layer deposition (ALD). Thus, a structure (300) according to FIG. 3 can be formed.

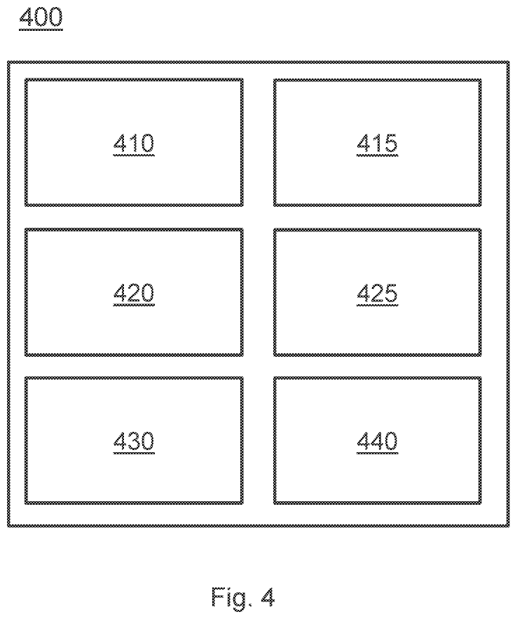

FIG. 4 shows an embodiment of a substrate processing system (400). The substrate processing system (400) comprises a first material layer reaction chamber (410). The first material layer reaction chamber (410) is arranged for forming a first material layer on a substrate. The substrate processing system (400) further comprises a first material etching chamber (415). The first material etching chamber (415) is arranged for removing the gap filling fluid from the substrate. The substrate processing system (400) further comprises a second material layer reaction chamber (420). The second material layer reaction chamber (420) is arranged for forming a second material layer on the substrate. The substrate processing system (400) further comprises a second material layer etching chamber (425). The second material layer etching chamber (425) is arranged for at least partially removing the material layer from the substrate. The substrate processing system (400) further comprises a wafer transfer robot (430). The wafer transfer robot (430) is arranged for moving a wafer between the first material reaction chamber, the first material etching chamber, the second material layer reaction chamber, and the second material layer etching chamber, without any intervening vacuum break. The substrate processing system (400) further comprises a controller (440). The controller (440) is arranged for causing the substrate processing system to carry out a method as described herein.

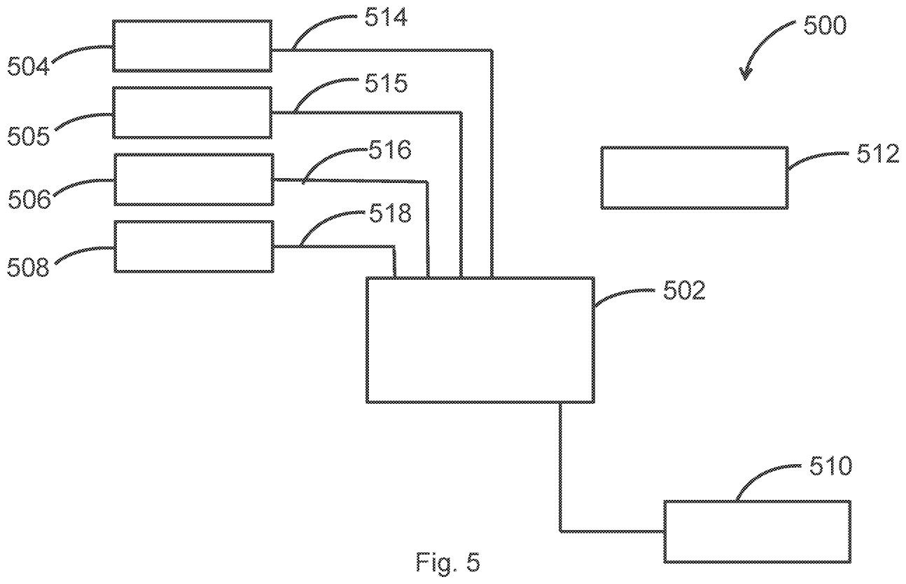

FIG. 5 illustrates a system (500) in accordance with exemplary embodiments of the disclosure. The system (500) can be configured to perform a method as described herein and/or form a structure or device portion as described herein.

In the illustrated example, the system (500) includes one or more reaction chambers (502), a first metal precursor vessel (504), a second metal precursor vessel (506), a chalcogenide reactant vessel (508), an exhaust (510), and a controller (512). In some embodiments, the system further comprises one or more of a dopant precursor vessel (not shown). The reaction chamber (502) can include an ALD reaction chamber.

The first precursor vessel (504) can include a container and one or more precursors as described herein-alone or mixed with one or more carrier (e.g., noble) gases. The second metal precursor vessel (506) can include a container and one or more dopant precursors as described herein-alone or mixed with one or more carrier gases. The oxygen reactant vessel (508) can include one or more oxygen reactants as described herein.

Although illustrated with four vessels (504)-(508), the system (500) can include any suitable number of vessels. The vessels (504)-(508) can be coupled to the reaction chamber (502) via lines (514)-(518), which can each include flow controllers, valves, heaters, and the like. The exhaust (510) can include one or more vacuum pumps.

The controller (512) includes electronic circuitry and software to selectively operate valves, manifolds, heaters, pumps and other components included in the system (500). Such circuitry and components operate to introduce precursors, reactants, and purge gases from the respective vessels (504)-(508).

The controller (512) can control timing of gas pulse sequences, temperature of the substrate and/or reaction chamber, pressure within the reaction chamber, and various other operations to provide proper operation of the system (500). The controller (512) can include control software to electrically or pneumatically control valves to control flow of precursors, reactants and purge gases into and out of the reaction chamber (502). The controller (512) can include modules such as a software or hardware component, e.g., a FPGA or ASIC, which performs certain tasks. A module can advantageously be configured to reside on the addressable storage medium of the control system and be configured to execute one or more processes as described herein.

Other configurations of the system (500) are possible, including different numbers and kinds of precursor and oxygen reactant vessels and optionally further including purge gas vessels. Further, it will be appreciated that there are many arrangements of valves, conduits, precursor vessels, and purge gas vessels that may be used to accomplish the goal of selectively feeding gases into the reaction chamber (502). Further, as a schematic representation of a system, many components have been omitted for simplicity of illustration, and such components may include, for example, various valves, manifolds, purifiers, heaters, containers, vents, and/or bypasses.

During operation of the system (500), substrates, such as semiconductor wafers (not illustrated), are transferred from, e.g., a substrate handling system to the reaction chamber (502). Once the substrate(s) are transferred to the reaction chamber (502), one or more gases from the vessels (504)-(508), such as precursors, reactants, carrier gases, and/or purge gases, are introduced into the reaction chamber (502).

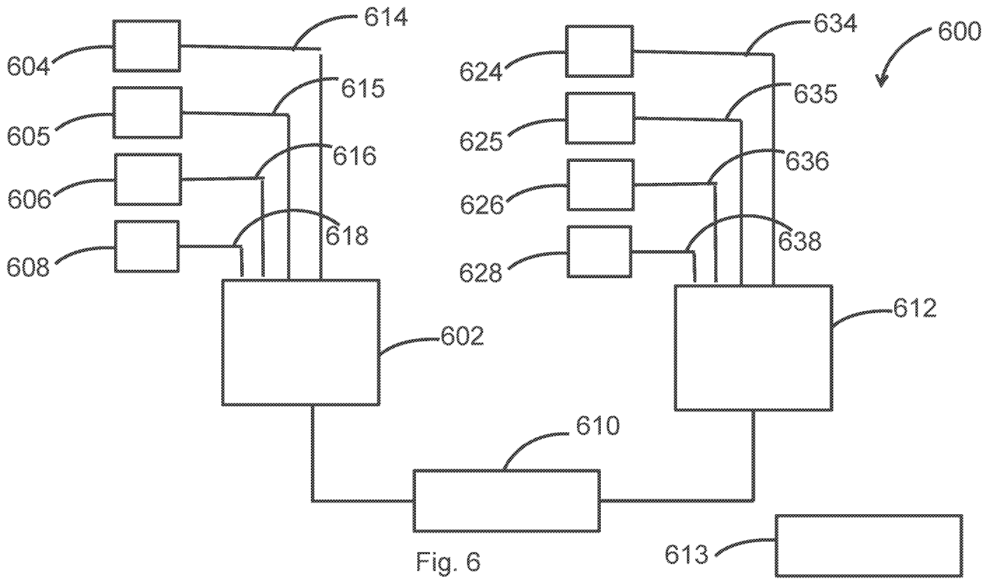

FIG. 6 illustrates a system (600) in accordance with exemplary embodiments of the disclosure. The system (600) can be configured to perform a method as described herein and/or form a structure or device portion as described herein.

In the illustrated example, the system (600) includes one or more reaction chambers (602), a first metal precursor vessel (604), a second metal precursor vessel (606), a chalcogenide reactant vessel (608), an exhaust (610), and a controller (613). In addition, the system (600) includes a second set of one or more reaction chambers (612), a first metal precursor vessel (624), a second metal precursor vessel (626), a chalcogenide reactant vessel (628). In some embodiments, the system further comprises one or more of a dopant precursor vessel (not shown). The reaction chamber (602, 612) can include an ALD reaction chamber.

The first precursor vessel (604, 624) can include a container and one or more precursors as described herein-alone or mixed with one or more carrier (e.g., noble) gases. The second metal precursor vessel (606, 626) can include a container and one or more dopant precursors as described herein-alone or mixed with one or more carrier gases. The oxygen reactant vessel (608, 628) can include one or more oxygen reactants as described herein.

Although illustrated with eight vessels (604)-(628), the system (600) can include any suitable number of vessels. The vessels (604)-(628) can be coupled to the reaction chamber (602, 612) via lines (614)-(638), which can each include flow controllers, valves, heaters, and the like. The exhaust (610) can include one or more vacuum pumps. The exhaust is connected to both reaction chambers (602, 612) via lines.

The controller (613) includes electronic circuitry and software to selectively operate valves, manifolds, heaters, pumps and other components included in the system (600). Such circuitry and components operate to introduce precursors, reactants, and purge gases from the respective vessels (604)-(628).

The controller (613) can control timing of gas pulse sequences, temperature of the substrates and/or reaction chambers, pressure within the reaction chambers, and various other operations to provide proper operation of the system (600). The controller (613) can include control software to electrically or pneumatically control valves to control flow of precursors, reactants and purge gases into and out of the reaction chambers (602, 612). The controller (612) can include modules such as a software or hardware component, e.g., a FPGA or ASIC, which performs certain tasks. A module can advantageously be configured to reside on the addressable storage medium of the control system and be configured to execute one or more processes as described herein.

Other configurations of the system (600) are possible, including different numbers and kinds of precursor and oxygen reactant vessels and optionally further including purge gas vessels. Further, it will be appreciated that there are many arrangements of valves, conduits, precursor vessels, and purge gas vessels that may be used to accomplish the goal of selectively feeding gases into the reaction chambers (602, 612). Further, as a schematic representation of a system, many components have been omitted for simplicity of illustration, and such components may include, for example, various valves, manifolds, purifiers, heaters, containers, vents, and/or bypasses.

During operation of the system (600), substrates, such as semiconductor wafers (not illustrated), are transferred from, e.g., a substrate handling system to the reaction chambers (602, 612). Once the substrate(s) are transferred to the reaction chamber (602), one or more gases from the vessels (604)-(628), such as precursors, reactants, carrier gases, and/or purge gases, are introduced into the reaction chambers (602, 612).

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of depositing p-type semiconducting oxide layer on a substrate by a cyclic deposition process, the method comprising the steps of:
providing a substrate in a reactor chamber;
executing a plurality of cycles, a cycle comprising:
i) providing a first and second metal precursor into the reactor chamber in vapor phase, the first metal precursor being provided during a first metal precursor pulse, the second metal precursor being provided during a second metal precursor pulse; and
ii) providing a chalcogenide reactant into the reactor chamber in vapor phase during a chalcogenide reactant pulse;
thus forming the layer on the substrate, wherein the first metal precursor is provided into the reactor chamber before the second metal precursor; the first and second metal precursor pulses are at least partially overlapping; and the first and second metal precursor are mutually different.

2. The method according to claim 1, wherein the first and second metal precursor each independently comprise a ligand chosen from the group consisting of: diketonate, alkoxide, diazadiene, amidinate, carboxylate, and cyclopentadienyl.

3. The method according to claim 1, wherein the first and second metal precursor comprise a metal atom that can be either nickel or copper.

4. The method according to claim 1, wherein the chalcogenide reactant is chosen from the group consisting of H₂O, H₂O₂, O₃, O₂, O-containing plasma, N₂O, NO, N₂O₅,O radicals, H₂S, H₂S plasma, H₂Se, Et₂Se, Se₂(Si(iPr)₂)₂, [(CH₃)₃Si]₂Se, [(CH₃)₃Si]₂Te and Te[OiPr]₄.

5. The method according to claim 1, wherein the cycle further comprises iii) providing a dopant precursor into the reaction chamber in a dopant precursor pulse.

6. The method according to claim 5, wherein the dopant precursor comprises one or more elements selected from the group consisting of Mn, Bi, Sr, B, N, Li, V, S, Sc, P, N, Ni, Ga, Mg, Cr, Sn, Sb, La, Y, Mo, and Al.

7. The method according to claim 5, wherein the dopant precursor comprises one or more elements selected from the group consisting of an alkali metal, an alkaline earth metal, a transition metal, a post transition metal, and a group 14 element.

8. The method according to claim 1, wherein the first and second precursors are provided into the reactor chamber at a temperature range of 80-400° C.

9. The method according to claim 1, wherein the pressure in the reaction chamber is between 0.1 and 100 Torr.

10. The method according to claim 1, wherein the first metal precursor pulse and the second metal precursor pulse are separated by a purge.

11. The method according to claim 1, wherein the method is carried out until a layer having a thickness in the range of 0.2 nm to 30 nm is formed on the substrate.

12. A memory element comprising:
a gate electrode;
a blocking dielectric, the blocking dielectric being adjacent to the gate electrode
a tunnel dielectric;
a charge trapping layer, the charge trapping layer being positioned between the blocking dielectric and the tunnel dielectric;
an n-type layer, the n-type layer being adjacent to the tunnel dielectric; and
a p-type layer, the p-type layer being adjacent to the n-type layer,
wherein the n-type layer comprises an n-type semiconducting oxide, and wherein the p-type layer comprises a p-type semiconducting oxide.

13. The memory element according to claim 12, wherein the p-type semiconducting oxide comprises nickel oxide (NiO).

14. The memory element according to claim 12, wherein the p-type semiconducting oxide comprises cuprous oxide (Cu₂O).

15. The memory element according to claim 12, wherein the n-type semiconducting oxide comprises oxygen and one or more of aluminum, gallium, indium, magnesium, scandium, tungsten, tin, and zinc.

16. The memory element according to claim 12, wherein the n-type layer is positioned between the tunnel dielectric and the p-type layer.

17. A gate stacked 3D NAND memory comprising a vertical channel and a plurality of floating gate stacks,
the floating gate stacks each comprising a tunnel dielectric adjacent to the vertical channel, a charge trapping layer adjacent to the tunnel dielectric, a blocking dielectric adjacent to the charge trapping layer, and a gate electrode adjacent to the blocking dielectric;
wherein the vertical channel comprises a p-type layer and an n-type layer, wherein the n-type layer comprises an n-type semiconducting oxide, and wherein the p-type layer comprises a p-type semiconducting oxide.

18. The gate stacked 3D NAND memory according to claim 17, wherein the p-type layer is deposited by the method according to claim 1.

19. The gate stacked 3D NAND memory according to claim 17, wherein the n-type layer forms a cylindrical shell around the p-type layer.

20. The gate stacked 3D NAND memory according to claim 17, further comprising the memory element according to claim 12.
